(19) United States
(12) Patent Application Publication
(10) Pub. No.: US 2023/0418160 A1
(43) Pub. Date: Dec. 28, 2023

(54) PHOTOSENSITIVE RESIN COMPOSITION, PROTECTIVE LAYER AND METHOD FOR PATTERN FORMATION

(71) Applicant: Advanced Echem Materials Company Limited, Taoyuan (TW)

(72) Inventors: Kuan-Ming Chen, Taoyuan (TW); Chi-Yu Lai, Taoyuan (TW)

(73) Assignee: Advanced Echem Materials Company Limited, Taoyuan (TW)

(21) Appl. No.: 18/342,754

(22) Filed: Jun. 28, 2023

(30) Foreign Application Priority Data
Jun. 28, 2022 (TW) 111123984

(51) Int. Cl. G03F 7/039; G03F 7/004; C08G 8/04

(52) U.S. Cl. CPC G03F 7/039; C08G 8/04; G03F 7/0045

(57) ABSTRACT

A photosensitive resin composition, a protective layer, and a method for pattern formation are provided. The photosensitive resin composition includes an alkali-soluble resin (A), a sensitizer (B), an additive (C), and a solvent (D). The additive (C) includes a compound represented by Formula (C-1) as follows. In Formula (C-1), the definitions of R¹ to R⁴ are as defined in the specification.

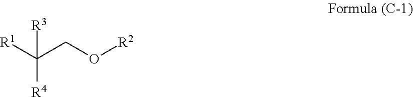

### CROSS-REFERENCE TO RELATED APPLICATION

This application claims the priority benefit of Taiwan application serial no. 111123984, filed on Jun. 28, 2022. The entirety of the above-mentioned patent application is hereby incorporated by reference herein and made a part of this specification.

### BACKGROUND

### Technical Field

The present disclosure relates to a resin composition, particularly to a photosensitive resin composition, a protective layer, and a method for pattern formation.

### Description of Related Art

Demands of semiconductor devices, display devices, and optical elements increase as these technologies are going through a vigorous development. Etching techniques are often used in the fabrication of semiconductor devices, display devices, and optical elements, but during the etching, the place between patterned upper and lower film layers is often suffered from significant side etching that compromises the reliability of the electronic elements and/or the display quality of the display device.

### SUMMARY

The disclosure provides a photosensitive resin composition, a protective layer, and a method for pattern formation capable of providing good adhesion.

The disclosure provides a photosensitive resin composition. The photosensitive resin composition includes an alkali-soluble resin (A), a sensitizer (B), an additive (C), and a solvent (D). The additive (C) includes a compound represented by Formula (C-1) as follows:

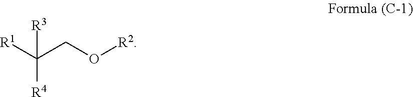

In Formula (C-1), R¹ represents hydrogen, hydroxyl, an alkyl group having 1 to 15 carbon atoms, a phenyl group, a phenyl group substituted by an aryl group, an acid group, an ester group, an alkylamino group, a halogen atom, a cyano group, or a combination thereof; R² represents a group represented by Formula (C-2) as follows; and R³ and R⁴ each represent hydrogen or a group represented by Formula (C-3) as follows:

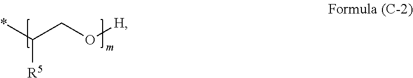

herein, R⁵ represents hydrogen or a methyl group, m represents an integer from 0 to 300, and * represents the bonding position;

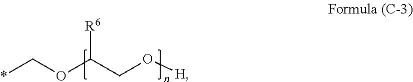

herein, R⁶ represents hydrogen or a methyl group, n represents an integer from 0 to 300, and * represents the bonding position.

In an embodiment of the disclosure, the alkali-soluble resin (A) includes phenolic resin.

In an embodiment of the disclosure, the sensitizer (B) includes a quinonediazide group-containing compound.

In an embodiment of the disclosure, the quinonediazide-containing compound includes a naphthoquinonediazide-containing compound.

In an embodiment of the disclosure, a usage amount of the additive (C) is 1000 ppm or more.

In an embodiment of the disclosure, the solvent (D) includes propylene glycol monomethyl ether acetate (PGMEA).

In the photosensitive resin composition of this disclosure, a sensitizer (E) is included, and the sensitizer (E) includes a compound represented by Formula (E-1) as follows:

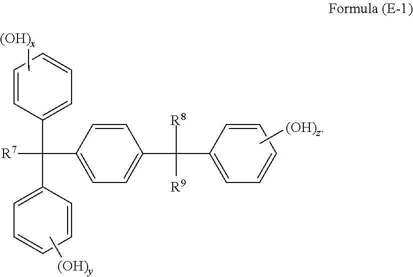

In Formula (E-1), R⁷ to R⁹ each represent hydrogen or an alkyl group having 1 to 3 carbon atoms, and x, y, and z each represent an integer of 1 to 3.

In the photosensitive resin composition of this disclosure, a sensitizer (E) is included, and the usage amount of the sensitizer (E) is 1 part by weight to 20 parts by weight based on 100 parts by weight of the alkali-soluble resin (A).

In the photosensitive resin composition of the disclosure, a surfactant (F) is included, and the surfactant (F) includes a polysiloxane-based surfactant, a fluorine-based surfactant, a nonionic surfactant, or a combination thereof.

In the photosensitive resin composition of this disclosure, based on 100 parts by weight of the alkali-soluble resin (A), the usage amount of the sensitizer (B) is 10 parts by weight to 35 parts by weight, and the usage amount of the solvent (D) is 200 parts by weight to 800 parts by weight.

A protective layer of the disclosure is formed of the photosensitive resin composition described above.

A method for pattern formation of the disclosure includes coating the photosensitive resin composition described above on a substrate.

Based on the above, as the photosensitive resin composition of the disclosure includes an additive (C) containing a compound with a specific structure, the protective layer formed of the photosensitive resin composition and the method for pattern formation using the photosensitive resin composition are able to provide good adhesion.

To make the features and advantages of the disclosure to be comprehended more easily, embodiments are described in detail as follows.

### DESCRIPTION OF THE EMBODIMENTS

### <Photosensitive Resin Composition>

The disclosure provides a photosensitive resin composition comprising an alkali-soluble resin (A), a sensitizer (B), an additive (C), and a solvent (D). In addition, the photosensitive resin composition of this disclosure may contain a sensitizer (E) and/or a surfactant (F) as needed. The components are described hereinafter in detail.

### Alkali-Soluble Resin (A)

The alkali-soluble resin (A) is not particularly limited, and any suitable alkali-soluble resin may be selected according to needs. For example, the alkali-soluble resin (A) may include phenolic resin, acrylic resin, polyhydroxystyrene resin, or other suitable alkali-soluble resin. Phenolic resins may be prepared by synthesizing p-cresol, m-cresol, benzaldehyde, and oxalic acid. The alkali-soluble resin (A) may be used alone or in combination of two or more alkali-soluble resin (A). In this embodiment, the alkali-soluble resin (A) is preferably phenolic resin.

The weight average molecular weight of the alkali-soluble resin (A) may be 2,000 to 30,000, preferably 4,000 to 20,000.

### Sensitizer (B)

The sensitizer (B) is not particularly limited, and any suitable sensitizer may be selected according to needs. The sensitizer (B) includes, for example, a quinonediazide group-containing compound, a hydroxybenzophenone-based compound, a hydroxyaromatic-based compound, or other suitable photosensitizers. The quinonediazide group-containing compound may include naphthoquinonediazide group-containing compounds, ester compounds of naphthoquinonediazide sulfonic acids, or other suitable quinonediazide group-containing compounds. The sensitizer (B) may be used alone or in combination of two or more sensitizer (B). In this embodiment, the sensitizer (B) is preferably a compound containing a naphthoquinonediazide group.

The usage amount of the sensitizer (B) is 10 to 35 parts by weight, preferably 20 to 30 parts by weight, based on 100 parts by weight of the alkali-soluble resin (A).

### Additive (C)

The additive (C) includes a compound represented by Formula (C-1) as follows. The additive (C) may further include adhesion aids or other suitable additives.

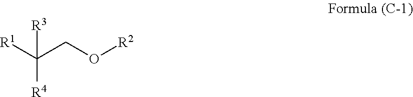

In Formula (C-1), R¹ represents hydrogen, hydroxyl, an alkyl group having 1 to 15 carbon atoms, a phenyl group, a phenyl group substituted by an aryl group, an acid group, an ester group, an alkylamino group, a halogen atom, a cyano group, or a combination thereof; R² represents a group represented by Formula (C-2) as follows; and R³ and R⁴ each represent hydrogen or a group represented by Formula (C-3) as follows.

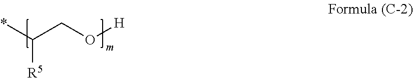

In Formula (C-2), R⁵ represents hydrogen or a methyl group, m represents an integer of 0 to 300, and * represents the bonding position.

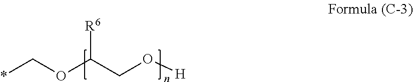

In Formula (C-3), R⁶ represents hydrogen or a methyl group, n represents an integer from 0 to 300, and * represents the bonding position.

In Formula (C-1), R¹ is preferably an alkyl group having 1 to 15 carbon atoms, a hydroxyl group, or a combination thereof; R² represents a group represented by Formula (C-2), wherein R⁵ is preferably hydrogen, and m is preferably an integer of 5 to 200; R³ and R⁴ are each preferably hydrogen.

The additive (C) may include a nonionic surfactant with a specific structure (e.g., the compound represented by Formula (C-1)), polyether polyol, or other suitable additives. For example, the nonionic surfactant with a specific structure may include alkyl ether type surfactants, alkylamino ether type surfactants, aryl phenyl ether type surfactants, fatty acid ether ester type surfactants, vegetable oil ether ester surfactants, or other suitable nonionic surfactant. The polyether polyols may include monool-type polyethers, glycol-type polyethers, polyol-type polyethers, or other suitable polyether polyols.

Specific examples of the additive (C) include Takesurf D-1203, Takesurf D-1205, Takesurf D-1212, Takesurf D-1305, Takesurf D-1323, Takesurf D-1402, Takesurf D-1420, Takesurf D-1502, Takesurf D-1508, Takesurf D-1518, Takesurf D-3102, Takesurf D-3104-F, Takesurf D-3110-F, Takesurf D-3120-W, Takesurf D-3605, Takesurf D-3615-T, Takesurf D-6112, Takesurf D-6115, Takesurf D-6120, Takesurf D-6131, Takesurf D-6105-W, Takesurf D-6108-W, Takesurf D-6112-W, Takesurf D-6120-X, Takesurf D-6512, Takesurf D-6413, Takesurf D-6414-M, Takesurf D-6320, Takesurf D-7010, Takesurf D-2104-D, Takesurf D-2507-A, Takesurf D-2513-A, Takesurf D-2504-D, Takesurf D-2506-D, Takesurf D-212, Takesurf D-220, Takesurf D-225, Takesurf D-230, Takesurf P-1050-B, Takesurf P-1550-B, Takesurf P-1028-P, Takesurf P-2517-P, Takesurf P-3429-P, Takesurf P-5050-P, Takesurf P-4050-T, Takesurf P-4070-T (trade name; manufactured by Takemoto Oil Co, Ltd.), SANNIX PP-1000, SANNIX PP-2000, SANNIX PP-3000, SANNIX PP-4000, SANNIX GP-3000, SANNIX GP-4000, SANNIX GP-5000, SANNIX FA703, SANNIX FA921, SANNIX FA908, and SANNIX FA961 (trade name; manufactured by YOUNG SUN CHEMTRADE CO., LTD.).

The usage amount of the additive (C) is not particularly limited in the photosensitive resin composition, and it may be used in any suitable amount according to needs. In this embodiment, the amount of the additive (C) in the photosensitive resin composition is preferably 1000 ppm or more, more preferably 1000 ppm to 5000 ppm.

When the additive (C) is included in the photosensitive resin composition, the protective layer formed by the photosensitive resin composition and the method for pattern formation using the photosensitive resin composition are able to provide better adhesion.

### Solvent (D)

The solvent (D) is not particularly limited, and any suitable solvent may be selected according to needs. For example, the solvent (D) includes propylene glycol monomethyl ether acetate, propylene glycol monomethyl ether, diethylene glycol methyl ether, or other suitable solvents. The solvent (D) may be used alone or in combination of two or more solvent (D). In this embodiment, the solvent (D) is preferably propylene glycol monomethyl ether acetate.

The usage amount of the solvent (D) is 200 to 800 parts by weight, preferably 600 to 800 parts by weight, based on 100 parts by weight of the alkali-soluble resin (A).

When the photosensitive resin composition includes the solvent (D), the photosensitive resin composition is able to have appropriate viscosity, which provides good coating uniformity to form a protective layer having good surface flatness.

### Sensitizer (E)

The sensitizer (E) is not particularly limited, and any suitable sensitizer may be selected according to needs. The sensitizer (E) may be used alone or in combination of two or more sensitizer (E).

The sensitizer (E) includes, for example, a compound represented by Formula (E-1) as follows, a polyhydroxybenzophenone-based compound, or other suitable sensitizers.

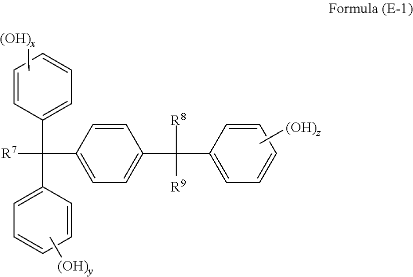

In Formula (E-1), R⁷ to R⁹ each represent hydrogen or an alkyl group having 1 to 3 carbon atoms, preferably a methyl group; and x, y, and z each represent an integer of 1 to 3, each preferably 1.

The usage amount of the sensitizer (E) is 1 to 20 parts by weight, preferably 5 to 10 parts by weight, based on 100 parts by weight of the alkali-soluble resin (A).

### Surfactant (F)

The surfactant (F) is not particularly limited, and any suitable surfactant may be selected according to needs. The surfactant (F) includes, for example, polysiloxane-based surfactants, fluorine-based surfactants, nonionic surfactants (except for the nonionic surfactants with a specific structure included in the additive (C)), or other suitable surfactants. For example, specific examples of the surfactant (F) includes KF-53, KF-54, KF-50-100CS, KF-56, KP-327, KBE-846, KBM-803 (trade name; manufactured by Shin-Etsu Chemical Co., Ltd.), BYK-323, BYK-3780, BYK-326, BYK-333, BYK-378, BYK-307, BYK-341, BYK-342, BYK-3460, BYK-3455, BYK-327, BYK-329, BYK-347, BYK-348, BYK-349, BYK-3451, BYK-346, BYK-370, BYK-373, BYK-3710, BYK-354, BYK-381, BYK-3440 (trade name; manufactured by BYK), SILFACE SAG003, SILFACE SWP-001, E1004 (trade name; manufactured by Nissin Chemical Co, Ltd.), PF-636, PF-6320, PF-656, PF-6520, PF-7002 (trade name; manufactured by OMNOVA), etc. The surfactant (F) may be used alone or in combination of two or more surfactant (F).

The usage amount of the surfactant (F) is 50 ppm to 2000 ppm, preferably 100 ppm to 1600 ppm, in the photosensitive resin composition.

### <Preparation of Photosensitive Resin Composition>

The preparation of the photosensitive resin composition is not particularly limited. For example, the alkali-soluble resin (A), the sensitizer (B), the additive (C), and the solvent (D) are stirred in a mixer to be mixed uniformly into a solution state, and a sensitizer (E) and/or a surfactant (F) may also be added if necessary. After mixing them uniformly, a liquid photosensitive resin composition is obtained.

### <Manufacturing Process of Protective Layer>

An exemplary embodiment of the disclosure provides a protective layer formed using the photosensitive resin composition.

The photosensitive resin composition is coated on a substrate with a base material, and the thin film is then subjected to processes including pre-baking, exposure, development, and post-baking to form a protective layer. For example, after the photosensitive resin composition is coated on the substrate to form the thin film, most of the solvent is removed by a vacuum drying process, followed by a pre-exposure baking (i.e., pre-baking) process for 120 seconds at 100° C. Next, the pre-baked thin film is exposed using an exposure machine. Then, the exposed thin film is developed for 60 seconds. Next, after the thin film is post-baked at 130° C. for 180 seconds, a protective layer having a thickness of about 1.5 μm is formed on the substrate.

The substrate may be a glass substrate, a plastic base material (for example, a polyether sulfone (PES) board, a polycarbonate (PC) board, or a polyimide (PI) film), or other light-transmitting substrates, and the type thereof is not particularly limited.

The substrate may be a metal layer or other etchable material layers, and the material thereof is not particularly limited. For example, the substrate may be a copper layer.

The coating technique is not particularly limited, but a spray coating, a roll coating, a spin coating, or a similar coating technique may be adopted. In general, the spin coating is a coating technique widely used. Furthermore, as a thin film is formed, the residual solvent may be partially removed under reduced pressure in some cases.

The developer is not particularly limited, and any suitable developer may be selected according to needs. For example, the developer may be tetramethyl ammonium hydroxide (TMAH), and its concentration may be 2.38 wt %.

### <Method for Pattern Formation>

An exemplary embodiment of the disclosure provides a method for pattern formation, including applying the photosensitive resin composition on a substrate.

The method for pattern formation may be similar to the manufacturing process of the protective layer, and after the post-baking that forms the protective layer, an etching process is further performed. For example, after the post-baking is completed, the post-baked protective layer may be further soaked in an etching liquid for 30 seconds to form a patterned protective layer on the substrate.

The etching liquid is not particularly limited, and any suitable etching liquid may be selected according to needs. For example, the etching liquid may be a copper etching liquid.

The disclosure is described hereinafter in detail with reference to some examples. The following examples are provided to describe the disclosure, and the scope of the disclosure includes the categories described in the following claims, their equivalents, and their modifications. The disclosure is not limited to the scope of those examples.

### Synthesis Example 1: Preparation of Phenolic Resin

A nitrogen gas inlet, a mixer, a heater, and a condenser were installed on a four-port separation-type reaction tank with a volume of 10 L. Then, nitrogen gas was introduced for 30 minutes. Next, 0.5 moles of p-cresol, 0.5 moles of m-cresol, 1.0 moles of benzaldehyde, and 0.015 moles of oxalic acid were added. The temperature was raised to 90° C. and the mixture was slowly stirred for 8 hours, such that the reactant was subjected to a condensation reaction at this temperature. Then, the solution was heated to 170° C. and dried under reduced pressure of 10 millimeters of mercury (mmHg). After the solvent is volatilized, the phenolic resin (A-1) is obtained.

### Synthesis Example 2: Preparation of Naphthoquinonediazide-Containing Compound

First, 0.5 moles of α,α,α′-tris(4-hydroxyphenyl)-1-ethyl-4-isopropylbenzene (TrisP-PA) and 1.5 moles of naphthoquinone-1,2-diazide-5-sulfonyl chloride was dissolved in dimethylacetamide to form a reaction solution. Then, the reaction solution was cooled to 30° C. using ice cubes. Next, 0.15 mol of triethylamine was added to the reaction solution as an alkaline catalyst, and the reaction was carried out for 2 hours. Then, triethylamine was filtered off, and the filtrate was poured into water to produce a precipitate. Next, the precipitate was collected by washing with water 3 times. Then, the solution containing the precipitate was heated to 60° C. and dried under reduced pressure of 10 mmHg. After drying, a naphthoquinonediazide group-containing compound (B-1) is obtained.

### Examples of Photosensitive Resin Composition and Protective Layer

Examples 1 to 3 and Comparative Examples 1 to 5 of the photosensitive resin composition and the protective layer are described hereinafter.

### Examples 1

a. Photosensitive Resin Composition

100 parts by weight of phenolic resin (A-1) (prepared by Synthesis Example 1), 22.5 parts by weight of naphthoquinonediazide-containing compound (B-1) (prepared by Synthesis Example 2), and 5000 ppm of Takesurf D-1203 (trade name; manufactured by Takemoto Oil Co, Ltd.) was added to 752 parts by weight of propylene glycol monomethyl ether acetate. After being stirred evenly with a mixer, the mixture was then filtered to obtain a photosensitive resin composition with a solvent content of 86%.

b. Protective Layer and Pattern Thereof

The photosensitive resin composition prepared in the examples were coated on a copper layer by spin coating (spin coater model Mark-Vz, manufactured by TOKYO ELECTRON Limited), and the copper layer is on the substrate. Then, most of the solvent was removed by a vacuum drying process (under pressure of 100 Pa), followed by a pre-baking process at 100° C. for 120 seconds to form a film. Then, the pre-baked film was exposed to light using an exposure machine (Model FX601, manufactured by Nikon Corporation) to form a semi-finished product. Next, a development process was performed for 60 seconds at 23° C. using tetramethylamine hydroxide (TMAH) having a concentration of 2.38% by weight as a developer. Then, a post-baking process was performed at 130° C. for 180 seconds, and a protective layer having a thickness of 1.5 μm was obtained. Next, the protective layer prepared so far was soaked in a copper etching liquid for 30 seconds to obtain a protective layer with a pattern thickness of 1.5 microns. The patterned protective layer was evaluated as follows, and the results are shown in Table 1.

### Example 2 to Example 3 and Comparative Example 1 to Comparative Example 5

The photosensitive resin compositions of Examples 2 to 3 and Comparative Examples 1 to 5 were prepared using the same procedure as that in Example 1. The difference is that the types and the usage amounts of the additive (C) in the photosensitive resin composition are changed (as shown in Table 1). The obtained photosensitive resin compositions were formed into patterned protective layers and were each evaluated as follows. The evaluation results are shown in Table 1.

TABLE 1

| Additive (C) | | Example | | | Comparative Example | | | | |
|---|---|---|---|---|---|---|---|---|---|
| (Unit: ppm) | | 1 | 2 | 3 | 1 | 2 | 3 | 4 | 5 |
| Takesurf D-1203 | | 5000 | 3000 | 1000 | — | — | — | — | — |
| Additive I | | — | — | — | 100 | 200 | — | — | — |
| Additive II | | — | — | — | — | — | 1000 | 2000 | — |
| Additive III | | — | — | — | — | — | — | — | 4000 |
| Evaluation | Adhesion | ○ | ○ | ○ | x | Δ | x | x | x |

Results

Takesurf D-1203: Trade name; manufactured by Takemoto Oil Co, Ltd.
Additive I: 3,4-dichloro-1,2,5-thiadiazole.
Additive II: 2-(5-tert-butyl-2-hydroxyphenyl)-2H benzotriazole.
Additive III: 4-(1,2,2-triphenylvinyl)phenol.

### <Evaluation Criteria>

a. Adhesion

The patterned protective layer (with a thickness of 1.5 μm) as prepared was subjected to a field emission electron microscope (FESEM) (Model SU8010, manufactured by Hitachi), to observe the side etching amount of the pattern and the copper layer below the pattern with a pattern width of 20 μm at the ratio of the exposed position to the unexposed position of 1:1, and the side etching amount of the pattern and the copper layer below the pattern with a pattern width of 30 μm at the ratio of the exposed position to the unexposed position of 1:1. A smaller side etching amount indicates a better adhesion of the protective layer.

The adhesion evaluation criteria are as follows:
◯: side etching amount ≤0.5 μm;
Δ: 0.5 μm<side etching amount≤2.0 μm;
x: 2.0 μm<side etching amount.

### <Evaluation Results>

It may be seen from Table 1 that the protective layers in Examples 1 to 3 in which the photosensitive resin composition includes the additive (C) containing the compound with the specific structure and the method for pattern formation using the same have good adhesion and may be applied to the manufacturing process of a semiconductor device, a display device, or an optical element. In contrast, the protective layers formed in Comparative Examples 1 to 5 in which the photosensitive resin composition did not include the additive (C) containing the compound with the specific structure have poor adhesion.

In addition, as shown in Table 1, when the unit of the usage amount of the additive (C) (Examples 1 to 3) containing a compound with a specific structure in the photosensitive resin composition is parts per million (ppm), that is, a very small amount, the protective layer and the method for pattern formation using the same are able to have good adhesion.

In summary, when the photosensitive resin composition of the disclosure includes the additive (C) containing the compound with the specific structure, the protective layer formed of the photosensitive resin composition and the method for pattern formation using the photosensitive resin composition have good adhesion, it may be applied to the manufacturing process of semiconductor devices, display devices, or optical elements to improve their performance.

Although the disclosure has been disclosed in the embodiments above, they are not intended to limit the disclosure. Anyone with ordinary knowledge in the relevant technical field can make changes and modifications without departing from the spirit and scope of the disclosure. The scope of protection of the disclosure shall be subject to those defined by the claims attached.

What is claimed is:

1. A photosensitive resin composition, comprising:
an alkali-soluble resin (A);
a sensitizer (B);
an additive (C); and
a solvent (D),
wherein the additive (C) comprises a compound represented by Formula (C-1) as follows: 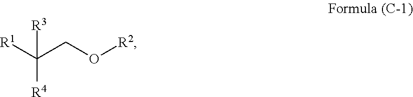
wherein R¹ represents hydrogen, hydroxyl, an alkyl group having 1 to 15 carbon atoms, a phenyl group, a phenyl group substituted by an aryl group, an acid group, an ester group, an alkylamino group, a halogen atom, a cyano group, or a combination thereof, R² represents a group represented by Formula (C-2) as follows, and R³ and R⁴ each represent hydrogen or a group represented by Formula (C-3) as follows, 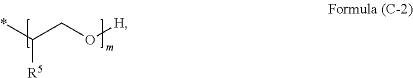
wherein R⁵ represents hydrogen or a methyl group, m represents an integer from 0 to 300, and * represents a bonding position, 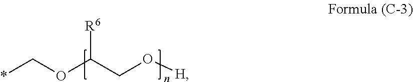
wherein R⁶ represents hydrogen or a methyl group, n represents an integer from 0 to 300, and * represents a bonding position.

2. The photosensitive resin composition according to claim 1, wherein the alkali-soluble resin (A) comprises phenolic resin.

3. The photosensitive resin composition according to claim 1, wherein the sensitizer (B) comprises a quinonediazide group-containing compound.

4. The photosensitive resin composition according to claim 3, wherein the quinonediazide group-containing compound comprises a naphthoquinonediazide group-containing compound.

5. The photosensitive resin composition according to claim 1, wherein a usage amount of the additive (C) is 1000 ppm or more.

6. The photosensitive resin composition according to claim 1, wherein the solvent (D) comprises propylene glycol monomethyl ether acetate.

7. The photosensitive resin composition according to claim 1, further comprising a sensitizer (E) comprising a compound represented by Formula (E-1) as follows: 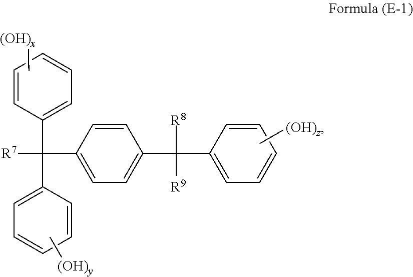
wherein R⁷ to R⁹ each represent hydrogen or an alkyl group having 1 to 3 carbon atoms, and x, y, and z each represent an integer of 1 to 3.

8. The photosensitive resin composition according to claim 1, further comprising a sensitizer (E), wherein a usage amount of the sensitizer (E) is 1 part by weight to 20 parts by weight based on 100 parts by weight of the alkali-soluble resin (A).

9. The photosensitive resin composition according to claim 1, further comprising a surfactant (F) comprising a polysiloxane-based surfactant, a fluorine-based surfactant, a nonionic surfactant, or a combination thereof.

10. The photosensitive resin composition according to claim 1, wherein, based on 100 parts by weight of the alkali-soluble resin (A), a usage amount of the sensitizer (B) is 10 parts by weight to 35 parts by weight, and a usage amount of the solvent (D) is 200 parts by weight to 800 parts by weight.

11. A protective layer formed of the photosensitive resin composition according to claim 1.

12. A method for pattern formation, comprising: coating the photosensitive resin composition according to claim 1 on a substrate.
